(19) United States
(12) Patent Application Publication
(10) Pub. No.: US 2026/0082849 A1
(43) Pub. Date: Mar. 19, 2026

(54) HEAT TREATMENT APPARATUS AND HEAT TREATMENT METHOD FOR HEATING SUBSTRATE BY LIGHT IRRADIATION

(71) Applicant: SCREEN Holdings Co., Ltd., Kyoto (JP)

(72) Inventors: Hiroyasu TAKEHARA, Kyoto-shi (JP); Yoshio ITO, Kyoto-shi (JP); Shinji MIYAWAKI, Kyoto-shi (JP); Kazuhiko FUSE, Kyoto-shi (JP)

(21) Appl. No.: 19/319,681

(22) Filed: Sep. 4, 2025

(30) Foreign Application Priority Data
Sep. 17, 2024 (JP) 2024-160123

(51) Int. Cl. H01L 21/67; F27B 17/00; F27D 5/00; F27D 7/02; H01L 21/687; H05B 3/00

(52) U.S. Cl. CPC H10P 72/0436; F27B 17/0025; F27D 5/0037; F27D 7/02; H05B 3/0047; H10P 72/7616

(57) ABSTRACT

A support ring which is an annular protrusion of quartz having a diameter smaller than that of a semiconductor wafer is provided upright on an upper surface of a holding plate of a susceptor. A flash of light is applied to a front surface of the semiconductor wafer supported by the support ring to heat the semiconductor wafer. When the semiconductor wafer is placed on the support ring, an enclosed space is formed which is surrounded by the upper surface of the holding plate, a lower surface of the semiconductor wafer, and an inner wall surface of the support ring. At the time of the flash irradiation, a force pressing from above is exerted on the front surface of the semiconductor wafer because of a pressure difference between the space overlying the semiconductor wafer and the enclosed space to prevent the semiconductor wafer from jumping.

### BACKGROUND

### Technical Field

The present invention relates to a heat treatment apparatus and a heat treatment method which irradiate a disk-shaped substrate with a flash of light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

In the flash lamp annealing, a front surface of a semiconductor wafer is momentarily irradiated with a flash of light having ultrahigh energy. Thus, the temperature of the front surface of the semiconductor wafer is raised rapidly in an instant, whereas the temperature of a back surface thereof does not rise so high. This causes abrupt thermal expansion of only the front surface of the semiconductor wafer, so that the semiconductor wafer becomes deformed in such a manner that the upper surface of the semiconductor wafer is warped in a convex form. Then, in the next instant, the semiconductor wafer becomes deformed as a reaction in such a manner that the lower surface of the semiconductor wafer is warped in a convex form. As a result, a phenomenon has occurred in which the semiconductor wafer vibrates violently on a susceptor which supports the semiconductor wafer to jump up from a plate and support pins of the susceptor. The semiconductor wafer jumping up from the susceptor comes into contact with the support pins when landing on the susceptor, which in some cases results in flaws in the back surface of the wafer or, in the worst case, cracking in the semiconductor wafer or the support pins.

To solve such a problem, Japanese Patent Application Laid-Open No. 2016-219719 discloses a technique which uses an elastic member such as an air spring to support a susceptor and to absorb and relax the force of the abrupt deformation of a semiconductor wafer when the semiconductor wafer is irradiated with a flash of light, thereby suppressing the jumping of the semiconductor wafer. U.S. Patent Application Publication No. 2014/0169772 discloses a technique which softens the impact of a falling semiconductor wafer by catching the semiconductor wafer jumping from a susceptor using a tapered surface when the semiconductor wafer is irradiated with a flash of light, to thereby prevent the semiconductor wafer from cracking.

The techniques disclosed in Japanese Patent Application Laid-Open No. 2016-219719 and U.S. Patent Application Publication No. 2014/0169772 are capable of preventing the semiconductor wafer from cracking to some extent. However, there is a need for a simpler configuration to suppress the jumping of the semiconductor wafer, thereby preventing the semiconductor wafer from cracking.

### SUMMARY

The present invention is intended for a heat treatment apparatus for irradiating a disk-shaped substrate with a flash of light to heat the substrate.

According to one aspect of the present invention, the heat treatment apparatus comprises: a chamber for receiving a substrate therein; a susceptor for holding the substrate in the chamber, the susceptor including a holding plate of quartz having a planar shape, and a protrusion of quartz having an annular shape, the protrusion being provided upright on an upper surface of the holding plate and having a diameter smaller than that of the substrate; and a flash lamp for irradiating the substrate held by the susceptor with a flash of light.

At the time of the flash irradiation, a force pressing from above is exerted on an upper surface of the substrate because of a pressure difference between the spaces overlying and underlying the substrate. This prevents the substrate from jumping at the time of the flash irradiation.

Preferably, the heat treatment apparatus further comprises a pressure reducing mechanism for reducing pressure in the enclosed space.

The pressure difference is reliably caused between the spaces overlying and underlying the substrate.

The present invention is also intended for a method of irradiating a disk-shaped substrate with a flash of light to heat the substrate.

According to one aspect of the present invention, the method comprises: (a) causing a susceptor to hold a substrate in a chamber; and (b) irradiating the substrate held by the susceptor with a flash of light from a flash lamp, wherein the susceptor includes a holding plate of quartz having a planar shape, and a protrusion of quartz having an annular shape, the protrusion being provided upright on an upper surface of the holding plate and having a diameter smaller than that of the substrate, and wherein the substrate is placed on the protrusion in the (a).

At the time of the flash irradiation, the force pressing from above is exerted on the upper surface of the substrate because of the pressure difference between the spaces overlying and underlying the substrate. This prevents the substrate from jumping at the time of the flash irradiation.

Preferably, pressure in the enclosed space surrounded by the upper surface of the holding plate, a lower surface of the substrate, and the protrusion is reduced.

The pressure difference is reliably caused between the spaces overlying and underlying the substrate.

It is therefore an object of the present invention to prevent a substrate from jumping when the substrate is irradiated with a flash of light.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a side view of the susceptor which holds a semiconductor wafer;

FIG. 5 is a plan view of a transfer mechanism;

FIG. 6 is a side view of the transfer mechanism;

FIG. 7 is a plan view showing an arrangement of halogen lamps;

FIG. 8 is a flow diagram showing a procedure for a treatment operation of a first preferred embodiment in the heat treatment apparatus of FIG. 1;

FIG. 9 is a view schematically showing a phenomenon which occurs at the time of flash irradiation;

FIG. 10 is a flow diagram showing a procedure for a treatment operation of a second preferred embodiment;

FIG. 11 is a view schematically showing that lift pins support the semiconductor wafer;

FIG. 12 is a view schematically showing that pressure in a chamber is reduced to less than atmospheric pressure while the lift pins support the semiconductor wafer;

FIG. 13 is a view schematically showing that the semiconductor wafer is placed on a support ring;

FIG. 14 is a view schematically showing that the pressure in the chamber is returned;

FIG. 15 is a view showing an example of a pressure reducing mechanism for reducing pressure in an enclosed space;

FIG. 16 is a flow diagram showing a procedure for a treatment operation of a third preferred embodiment; and

FIGS. 17 to 20 are plan views showing examples of other forms of the support ring.

### DESCRIPTION OF THE PREFERRED EMBODIMENTS

Preferred embodiments according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

### First Preferred Embodiment

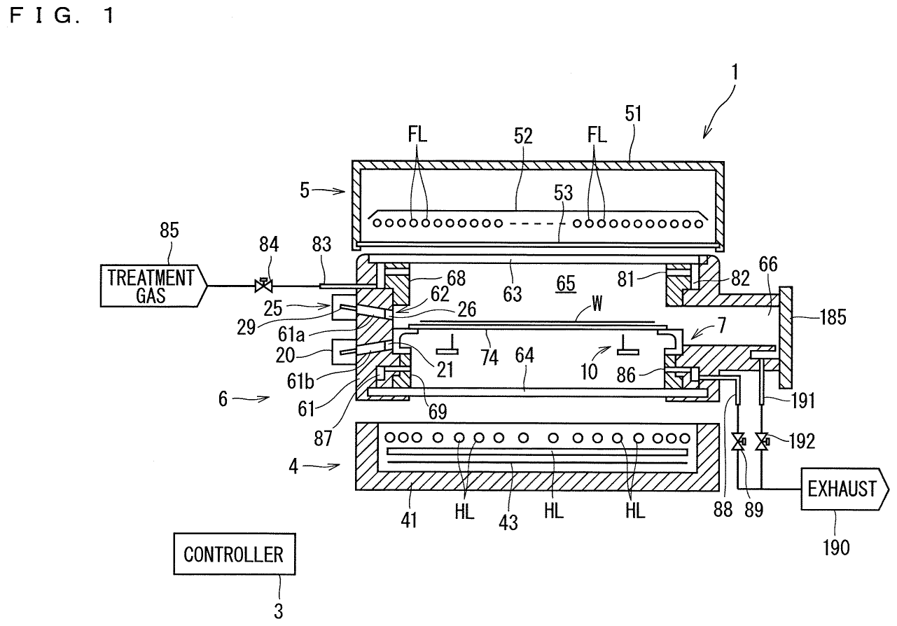

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm (in the present preferred embodiment, 300 mm). It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a and a through hole 61b both bored therein. The through hole 61a is a cylindrical hole for directing infrared light emitted from an upper surface of a semiconductor wafer W held by a susceptor 74 to be described later therethrough to an infrared sensor 29 of an upper radiation thermometer 25. The through hole 61b is a cylindrical hole for directing infrared light emitted from a lower surface of the semiconductor wafer W therethrough to a lower radiation thermometer 20. The through holes 61a and 61b are inclined with respect to a horizontal direction so that the longitudinal axes (axes extending in respective directions in which the through holes 61a and 61b extend through the chamber side portion 61) of the respective through holes 61a and 61b intersect main surfaces of the semiconductor wafer W held by the susceptor 74. A transparent window 26 made of calcium fluoride material transparent to infrared light in a wavelength range measurable with the upper radiation thermometer 25 is mounted to an end portion of the through hole 61a which faces the heat treatment space 65. A transparent window 21 made of barium fluoride material transparent to infrared light in a wavelength range measurable with the lower radiation thermometer 20 is mounted to an end portion of the through hole 61b which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

The exhaust part 190 includes a vacuum pump. By operating the exhaust part 190 to exhaust the gas in the heat treatment space 65 without supplying gas through the gas supply opening 81, pressure in the chamber 6 is reduced to less than atmospheric pressure. In other words, the exhaust part 190 functions also as a pressure reducing part.

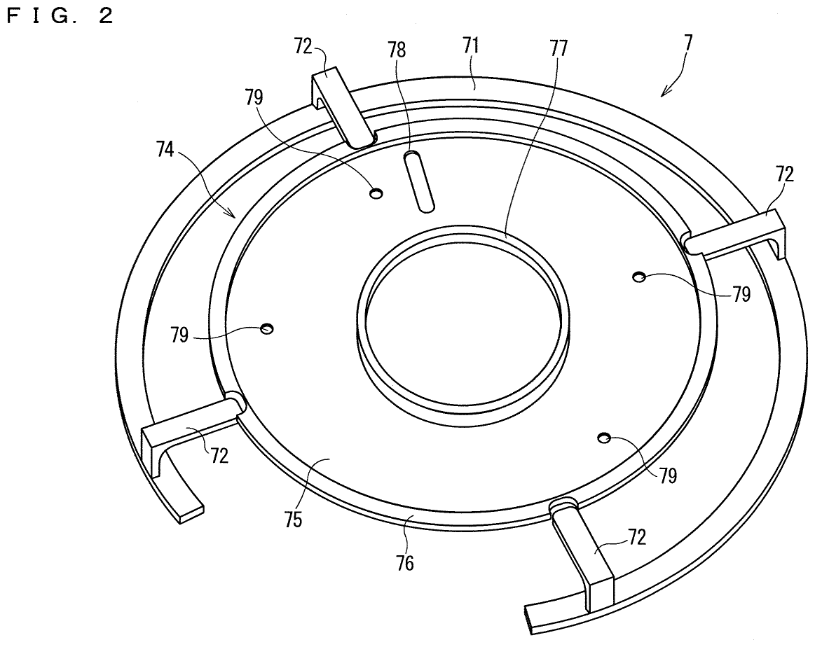

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

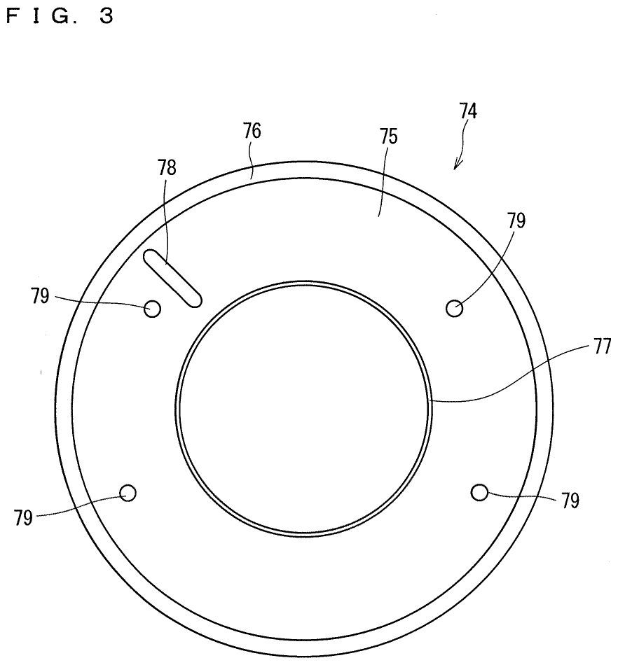

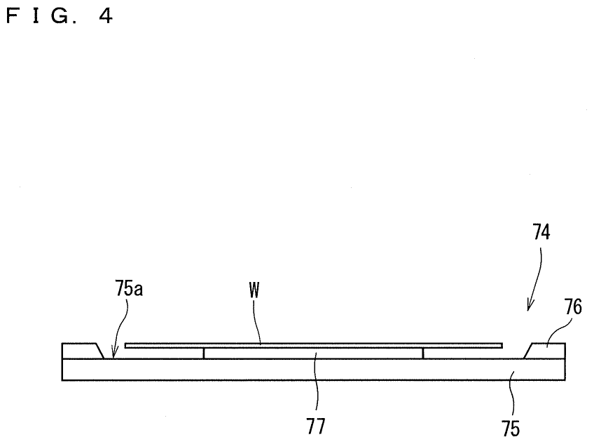

The susceptor 74 is supported by the four coupling portions 72 provided on the base ring 71. FIG. 3 is a plan view of the susceptor 74. FIG. 4 is a side view of the susceptor 74 which holds the semiconductor wafer W. The susceptor 74 includes a holding plate 75, a guide ring 76, and a support ring 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The support ring 77 is provided upright on the holding surface 75a of the holding plate 75. The support ring 77 is a protrusion having an annular shape. The support ring 77 is provided on the upper surface of the holding plate 75 so that the annular shape thereof is concentric with the outer circumference of the holding surface 75a (the inner circumference of the guide ring 76). The diameter of the annular support ring 77 is smaller than the diameter (in the first preferred embodiment, 300 mm) of the semiconductor wafer W, and is 180 mm in the first preferred embodiment. The support ring 77 is made of quartz. The support ring 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the lower surface of the semiconductor wafer W is supported by the support ring 77, so that the semiconductor wafer W is held by the susceptor 74. When the semiconductor wafer W is placed on the support ring 77, an enclosed space is formed which is surrounded by the upper surface of the holding plate 75, the lower surface of the semiconductor wafer W, and an inner wall surface of the support ring 77.

The semiconductor wafer W supported by the support ring 77 is spaced a predetermined distance apart from the holding surface 75a of the holding plate 75. The thickness of the guide ring 76 is greater than the height of the support ring 77. Thus, the guide ring 76 prevents the horizontal misregistration of the semiconductor wafer W supported by the support ring 77.

As shown in FIGS. 2 and 3, an opening 78 is formed in the holding plate 75 of the susceptor 74 so as to extend vertically through the holding plate 75 of the susceptor 74. The opening 78 is provided for the lower radiation thermometer 20 to receive radiation (infrared light) emitted from the lower surface of the semiconductor wafer W. Specifically, the lower radiation thermometer 20 receives the radiation emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W. The holding surface 75a of the holding plate 75 has no opening inside the support ring 77.

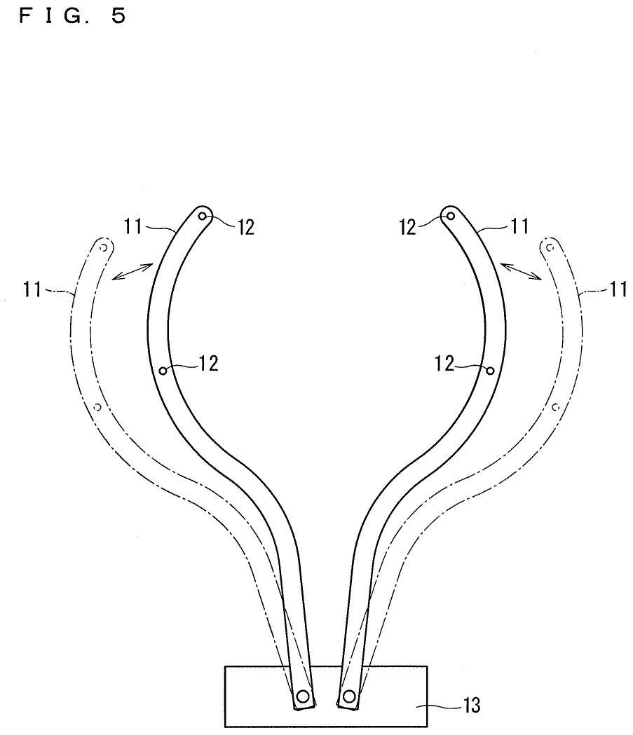

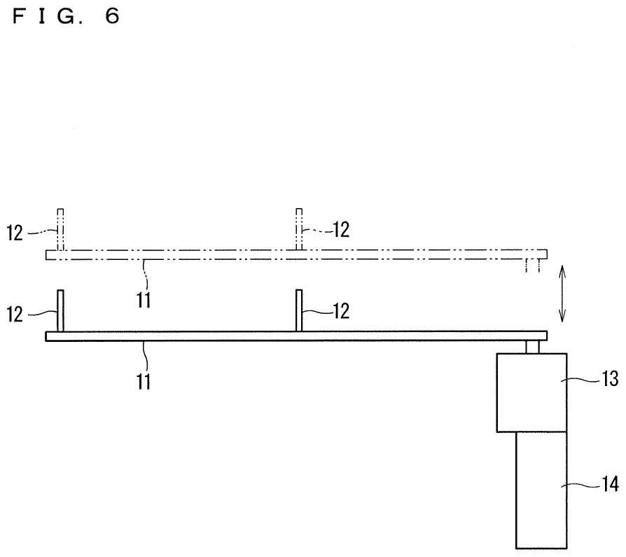

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 directs light from under the chamber 6 through the lower chamber window 64 toward the heat treatment space 65 to heat the semiconductor wafer W by means of the halogen lamps HL.

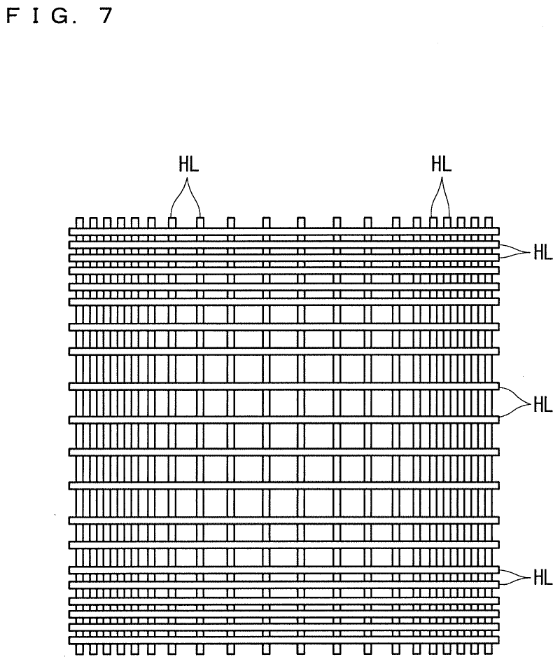

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

As shown in FIG. 1, the heat treatment apparatus 1 includes the upper radiation thermometer 25 and the lower radiation thermometer 20. The upper radiation thermometer 25 is provided obliquely above the semiconductor wafer W held by the susceptor 74, and receives the infrared radiation emitted from the upper surface of the semiconductor wafer W to measure the temperature of the upper surface of the semiconductor wafer W. The infrared sensor 29 of the upper radiation thermometer 25 includes an optical element made of InSb (indium antimonide) so as to be able to respond to rapid changes in temperature of the upper surface of the semiconductor wafer W at the moment of flash irradiation. On the other hand, the lower radiation thermometer 20 is provided obliquely below the semiconductor wafer W held by the susceptor 74, and receives the infrared radiation emitted from the lower surface of the semiconductor wafer W to measure the temperature of the lower surface of the semiconductor wafer W.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 1 proceed.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

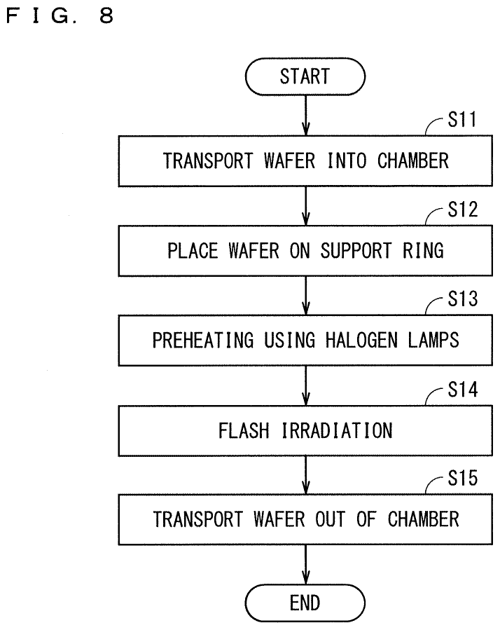

Next, a treatment operation in the heat treatment apparatus 1 having the aforementioned configuration will be described. FIG. 8 is a flow diagram showing a procedure for the treatment operation of the first preferred embodiment in the heat treatment apparatus 1. The treatment procedure of the heat treatment apparatus 1 which will be described below proceeds under the control of the controller 3 over the operating mechanisms of the heat treatment apparatus 1.

Prior to the treatment of the semiconductor wafer W, the valve 84 for supply of gas is opened, and the valves 89 and 192 for exhaust of gas are opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. When the valve 192 is further opened, the gas within the chamber 6 is exhausted also through the transport opening 66. This causes the nitrogen gas supplied from an upper portion of the heat treatment space 65 in the chamber 6 to flow downwardly and then to be exhausted from a lower portion of the heat treatment space 65.

Subsequently, the gate valve 185 is opened to open the transport opening 66. A transport robot outside the heat treatment apparatus 1 transports the disk-shaped semiconductor wafer W to be treated through the transport opening 66 into the heat treatment space 65 of the chamber 6 (Step S11). At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above an upper end of the support ring 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is placed on the support ring 77 provided upright on the holding plate 75, and is held by the susceptor 74 (Step S12). The semiconductor wafer W is held by the holder 7 in such an attitude that the front surface thereof that is a surface to be treated is the upper surface. A region of the holding plate 75 which is inside the support ring 77 is provided with no opening. Thus, when the semiconductor wafer W is placed on the support ring 77, the enclosed space is formed which is surrounded by the upper surface of the holding plate 75, a back surface (a main surface opposite from the front surface) of the semiconductor wafer W, and the inner wall surface of the support ring 77. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the 40 halogen lamps HL in the halogen heating part 4 turn on simultaneously to start preheating (or assist-heating) (Step S13). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured by the lower radiation thermometer 20 when the halogen lamps HL perform the preheating. Specifically, the lower radiation thermometer 20 receives infrared radiation emitted from the lower surface of the semiconductor wafer W held by the susceptor 74 through the opening 78 and passing through the transparent window 21 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the lower radiation thermometer 20. In this manner, the lower radiation thermometer 20 is a radiation thermometer for controlling the temperature of the semiconductor wafer W during the preheating.

After the temperature of the semiconductor wafer W reaches the preheating temperature T1, the controller 3 maintains the temperature of the semiconductor wafer W at the preheating temperature T1 for a short time. Specifically, when the temperature of the semiconductor wafer W measured by the lower radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in the peripheral portion thereof where heat dissipation is liable to occur than in the central portion thereof. However, the halogen lamps HL in the halogen heating part 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL in the flash heating part 5 irradiate the front surface of the semiconductor wafer W held by the susceptor 74 with a flash of light (Step S14) when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. By the irradiation with a flash of light which is extremely short in irradiation time and high in intensity, the front surface temperature of the semiconductor wafer W momentarily increases to a treatment temperature T2 of 1000° C. or higher, and thereafter decreases rapidly.

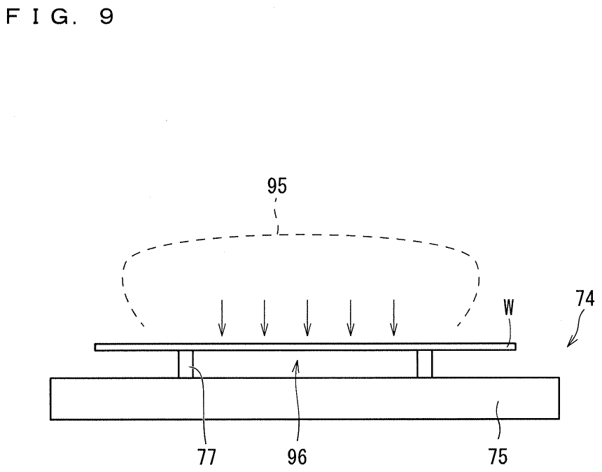

FIG. 9 is a view schematically showing a phenomenon which occurs at the time of the flash irradiation. When the semiconductor wafer W is irradiated with a flash of light from the flash lamps FL, the temperature of the front surface of the semiconductor wafer W momentarily increases to a relatively high temperature of 1000° C. or higher, so that pressure in a space 95 in the vicinity of the front surface increases. On the other hand, the temperature of the back surface of the semiconductor wafer W does not significantly increase, so that pressure in an enclosed space 96 surrounded by the upper surface of the holding plate 75, the back surface of the semiconductor wafer W, and the inner wall surface of the support ring 77 is kept relatively low. As a result, as shown in FIG. 9, a force pressing from above is exerted on the front surface of the semiconductor wafer W due to a pressure difference between the space 95 overlying the semiconductor wafer W and the enclosed space 96 to suppress the deformation of the semiconductor wafer W into a convex form and to prevent the semiconductor wafer W from jumping up from the susceptor 74. This reduces flaws in the back surface of the semiconductor wafer W resulting from the jumping of the semiconductor wafer W to prevent the semiconductor wafer W from cracking.

After a predetermined time period has elapsed since the completion of the flash heating treatment, the halogen lamps HL turn off. This causes the temperature of the semiconductor wafer W to decrease rapidly from the preheating temperature T1. The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed (Step S15).

In the first preferred embodiment, the support ring 77 which is an annular protrusion of quartz having a diameter smaller than that of the semiconductor wafer W is provided upright on the upper surface of the holding plate 75 of the susceptor 74. During the treatment of the semiconductor wafer W, the semiconductor wafer W is placed on the support ring 77 and is held by the susceptor 74. When the semiconductor wafer W is placed on the support ring 77, the enclosed space 96 surrounded by the upper surface of the holding plate 75, the lower surface of the semiconductor wafer W, and the inner wall surface of the support ring 77 is formed. At the time of the flash irradiation, the force pressing from above is exerted on the front surface of the semiconductor wafer W due to the pressure difference between the space 95 overlying the semiconductor wafer W and the enclosed space 96 to suppress the jumping of the semiconductor wafer W. That is, a simple configuration such that the support ring 77 having an annular shape is provided in the susceptor 74 prevents the semiconductor wafer W from jumping during the flash irradiation to prevent the wafer cracking, and also improves yields.

In the first preferred embodiment, the support ring 77 smaller in diameter than the semiconductor wafer W supports the semiconductor wafer W. The outer peripheral edge of the semiconductor wafer W is an open edge because the support ring 77 supports part of the semiconductor wafer W which is inside the outer peripheral edge. Thus, the outer peripheral edge of the semiconductor wafer W can move to some extent even during the flash irradiation, and no strong reaction stress is exerted on the semiconductor wafer W. This prevents the semiconductor wafer W from cracking more effectively.

### Second Preferred Embodiment

Next, a second preferred embodiment of the present invention will be described. A heat treatment apparatus of the second preferred embodiment has the same configuration as the heat treatment apparatus 1 of the first preferred embodiment. In the second preferred embodiment, a reduced-pressure atmosphere is produced in the enclosed space 96.

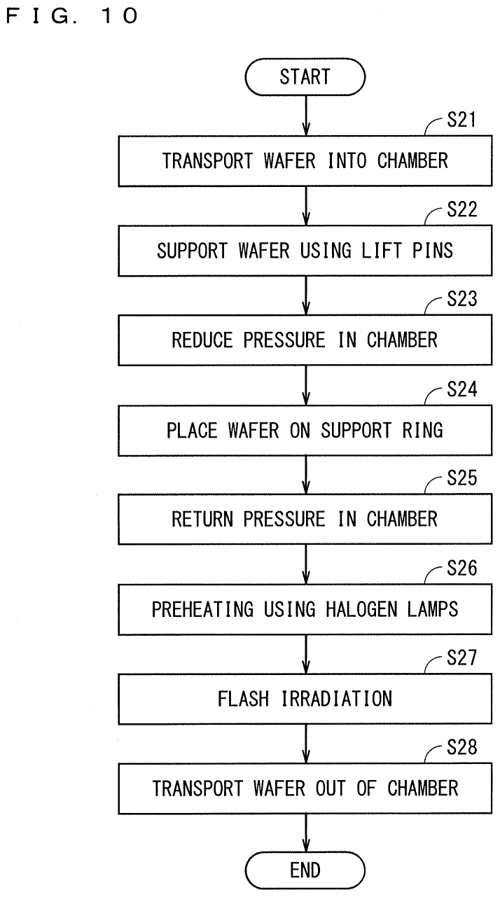

FIG. 10 is a flow diagram showing a procedure for the treatment operation of the second preferred embodiment. First, as in the first preferred embodiment, the supply and exhaust of nitrogen gas into and out of the chamber 6 start, and the semiconductor wafer W is transported into the chamber 6 (Step S21). The semiconductor wafer W transported into the chamber 6 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. In the second preferred embodiment, the lift pins 12 wait for a short time while moved upwardly above the support ring 77, and keep supporting the semiconductor wafer W (Step S22).

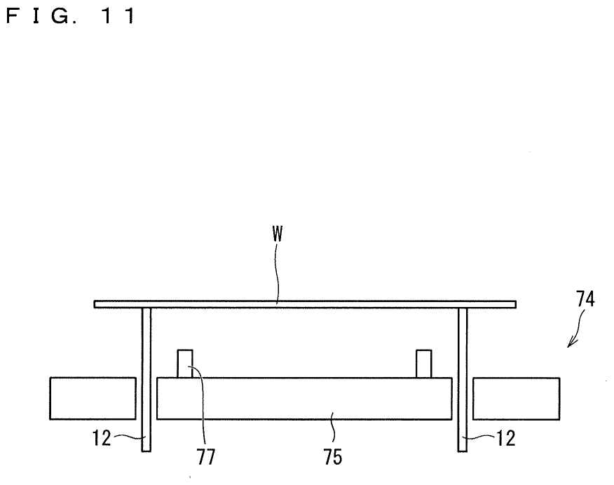

FIG. 11 is a view schematically showing that the lift pins 12 support the semiconductor wafer W. The lift pins 12 move upwardly, so that the upper ends of the lift pins 12 protrude from the holding plate 75 and are positioned above the support ring 77. Thus, the semiconductor wafer W supported by the lift pins 12 is not in contact with the support ring 77, and a space underlying the semiconductor wafer W is an open space. In other words, the aforementioned enclosed space 96 is not formed at this point of time.

Next, the pressure in the chamber 6 is reduced (Step S23), with the semiconductor wafer W supported by the lift pins 12. Specifically, the valve 84 for supply of gas is closed, and the valves 89 and 192 for exhaust of gas are opened, while the exhaust part 190 including the vacuum pump is in operation, to exhaust the atmosphere in the chamber 6, thereby reducing the pressure in the chamber 6 to less than atmospheric pressure. At this time, the pressure in the chamber 6 is reduced to a first pressure (e.g., 100 Pa).

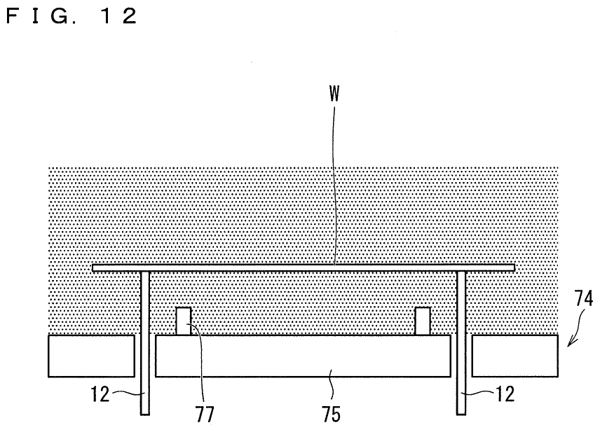

FIG. 12 is a view schematically showing that the pressure in the chamber 6 is reduced to less than atmospheric pressure while the lift pins 12 support the semiconductor wafer W. The inside of the support ring 77 is not an enclosed space but is open. For this reason, when the pressure in the chamber 6 is reduced to the first pressure, pressure in the space underlying the semiconductor wafer W, including the inside of the support ring 77, also reaches the first pressure.

After the pressure in the chamber 6, including the inside space of the support ring 77, is reduced to the first pressure, the lift pins 12 move downwardly, so that the semiconductor wafer W is placed on the support ring 77 (Step S24). More specifically, as the pair of transfer arms 11 moves downwardly, the lift pins 12 also move downwardly to below the holding plate 75. As a result, the semiconductor wafer W supported by the lift pins 12 is transferred to and placed on the support ring 77.

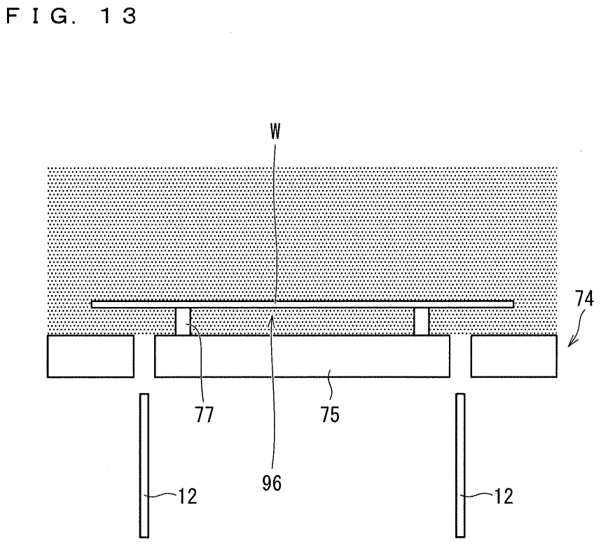

FIG. 13 is a view schematically showing that the semiconductor wafer W is placed on the support ring 77. When the semiconductor wafer W is placed on the support ring 77, the enclosed space 96 surrounded by the upper surface of the holding plate 75, the back surface of the semiconductor wafer W, and the inner wall surface of the support ring 77 is formed. In the second preferred embodiment, the semiconductor wafer W is placed on the support ring 77, with the pressure in the chamber 6 reduced to the first pressure. For this reason, the pressure in the enclosed space 96 is also equal to the first pressure less than atmospheric pressure. At this point of time, the pressure in the space overlying the semiconductor wafer W is also equal to the first pressure.

Thereafter, with the semiconductor wafer W on the support ring 77, the pressure in the chamber 6 is returned (Step S25). Specifically, the valve 84 for supply of gas is opened for a short time to supply a small amount of nitrogen gas into the chamber 6, thereby increasing the pressure in the chamber 6 from the first pressure to a second pressure. At this time, the valves 89 and 192 for exhaust of gas may be left open or closed once. The second pressure is higher than the first pressure, and is 5000 Pa, for example. A large amount of nitrogen gas may be supplied into the chamber 6 to return the pressure in the chamber 6 to ordinary pressure (0.1 MPa).

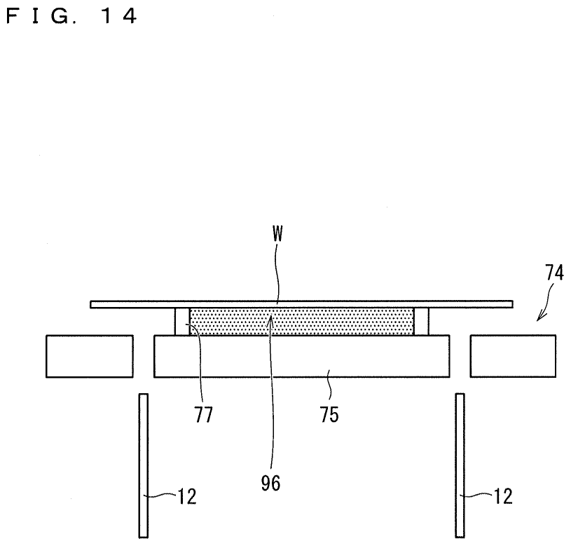

FIG. 14 is a view schematically showing that the pressure in the chamber 6 is returned. Even if the pressure in the chamber 6 is returned to the second pressure, the atmosphere in the chamber 6 does not flow into the enclosed space 96. For this reason, the pressure in the enclosed space 96 is maintained at the first pressure. On the other hand, the pressure in the chamber 6 except the enclosed space 96 is returned to the second pressure. Thus, there arises a pressure difference between the space overlying the semiconductor wafer W supported by the support ring 77 and the enclosed space 96.

The details of processes in Steps S26 to S28 are the same as those in Steps S13 to S15 of FIG. 8, respectively. Specifically, after the semiconductor wafer W is supported by the support ring 77 and the pressure in the chamber 6 is returned, the 40 halogen lamps HL in the halogen heating part 4 emit light to preheat the semiconductor wafer W (Step S26). The temperature of the semiconductor wafer W is measured by the lower radiation thermometer 20 when the halogen lamps HL perform the preheating. The controller 3 effects feedback control of the output from the halogen lamps HL so that the temperature of the semiconductor wafer W is equal to the preheating temperature T1, based on the value measured by the lower radiation thermometer 20.

The flash lamps FL in the flash heating part 5 irradiate the front surface of the semiconductor wafer W held by the susceptor 74 with a flash of light (Step S27) when a predetermined time period has elapsed since the temperature of the semiconductor wafer W reached the preheating temperature T1. By the irradiation with a flash of light which is extremely short in irradiation time and high in intensity, the front surface temperature of the semiconductor wafer W momentarily increases to the treatment temperature T2 of 1000° C. or higher, and thereafter decreases rapidly.

In the second preferred embodiment, there has been a pressure difference between the space overlying the semiconductor wafer W and the enclosed space 96 since before the flash irradiation, and the force pressing from above is exerted on the front surface of the semiconductor wafer W even when the temperature of the front surface of the semiconductor wafer W increases abruptly at the time of the flash irradiation. This suppresses the deformation of the semiconductor wafer W into a convex form at the time of the flash irradiation and prevents the semiconductor wafer W from jumping up from the susceptor 74. As a result, the second preferred embodiment reduces flaws in the back surface of the semiconductor wafer W resulting from the jumping of the semiconductor wafer W to prevent the semiconductor wafer W from cracking.

After a predetermined time period has elapsed since the completion of the flash heating treatment, the halogen lamps HL turn off. This causes the temperature of the semiconductor wafer W to decrease from the preheating temperature T1. After the temperature of the semiconductor wafer W is decreased to the predetermined temperature or below, the transport robot outside the heat treatment apparatus 1 transports the semiconductor wafer W out of the chamber 6 (Step S28).

In the second preferred embodiment, the pressure in the chamber 6 is reduced to the first pressure before the semiconductor wafer W is placed on the support ring 77, and the pressure in the chamber 6 is then returned to the second pressure after the semiconductor wafer W is placed on the support ring 77. As a result, at the time of the flash irradiation, the pressure in the enclosed space 96 surrounded by the upper surface of the holding plate 75, the lower surface of the semiconductor wafer W, and the inner wall surface of the support ring 77 is equal to the first pressure, whereas the pressure in the chamber 6 except the enclosed space 96 is equal to the second pressure. This causes the pressure difference to arise between the space overlying the semiconductor wafer W and the enclosed space 96. Thus, at the time of the flash irradiation, the force pressing from above is exerted on the front surface of the semiconductor wafer W due to the pressure difference to prevent the semiconductor wafer W from jumping, thereby preventing wafer cracking, as in the first preferred embodiment.

In the second preferred embodiment, the reduced-pressure atmosphere is intentionally produced in the enclosed space 96. This allows the pressure difference to arise with reliability between the space overlying the semiconductor wafer W and the enclosed space 96. Thus, the force pressing from above is exerted more effectively on the semiconductor wafer W to prevent the semiconductor wafer W from jumping.

### Third Preferred Embodiment

Next, a third preferred embodiment of the present invention will be described. In the third preferred embodiment, the reduced-pressure atmosphere is produced in the enclosed space 96 as in the second preferred embodiment, but a dedicated pressure reducing mechanism is provided for this purpose.

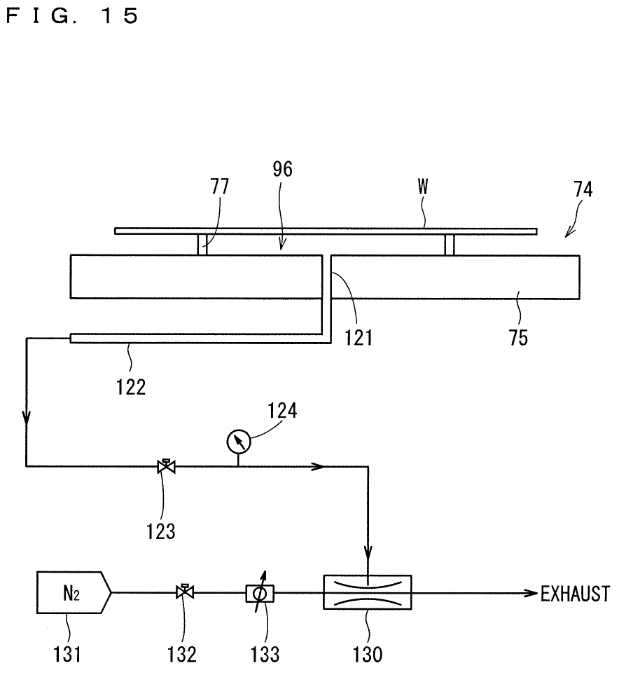

FIG. 15 is a view showing an example of the pressure reducing mechanism for reducing the pressure in the enclosed space 96. Like reference numerals and characters are used in FIG. 15 to designate components identical with those of the first preferred embodiment. As in the first preferred embodiment, when the semiconductor wafer W is placed on the support ring 77, the enclosed space 96 surrounded by the upper surface of the holding plate 75, the lower surface of the semiconductor wafer W, and the inner wall surface of the support ring 77 is formed. In the third preferred embodiment, an exhaust port 121 is provided in the vicinity of the center of the holding plate 75 of the susceptor 74. The exhaust port 121 is provided so as to extend vertically through the holding plate 75, and has a tip opening in communication with the enclosed space 96. The exhaust port 121 may be formed integrally with the holding plate 75 or be a component independent of the holding plate 75.

The exhaust port 121 is connected to an exhaust pipe 122. The exhaust pipe 122 has a first end connected to the exhaust port 121 and a second end connected to an ejector 130. A valve 123 and a pressure sensor 124 are interposed in the exhaust pipe 122.

The ejector 130 is a device which creates a reduced-pressure state through a Venturi effect using a fluid. When a valve 132 is opened, high-pressure nitrogen gas is fed from a nitrogen supply source 131 to the ejector 130. The pressure of the fed nitrogen gas is regulated by a regulator 133. When the high-pressure nitrogen gas flows through a pipe of the ejector 130, a negative pressure is generated in the surroundings thereof. The negative pressure is applied through the exhaust pipe 122 to the exhaust port 121 if the valve 123 is open. That is, the flow of the high-pressure nitrogen gas through the ejector 130 causes the negative pressure to be exerted on the exhaust port 121, resulting in the pressure reduction in the enclosed space 96. The nitrogen gas passing through the ejector 130 is exhausted together with the gas sucked in through the exhaust port 121. The fluid fed to the ejector 130 is not limited to nitrogen gas, but may be air, for example. The remaining components of the heat treatment apparatus in the third preferred embodiment are the same as those in the first preferred embodiment except that the pressure reducing mechanism for reducing the pressure in the enclosed space 96 is provided.

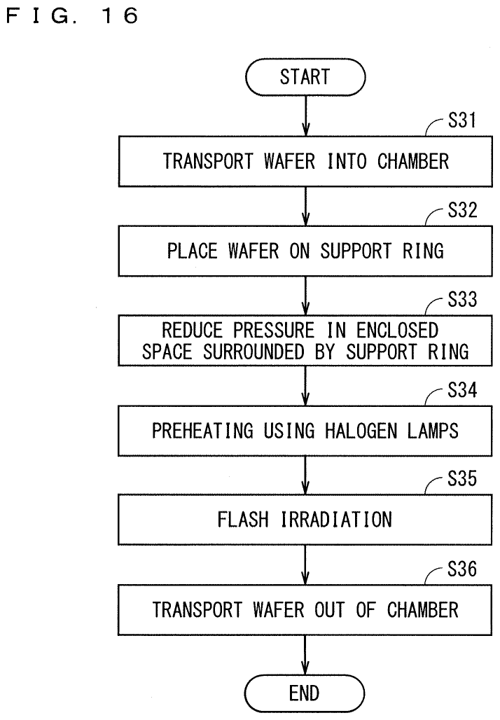

FIG. 16 is a flow diagram showing a procedure for the treatment operation of the third preferred embodiment. First, as in the first preferred embodiment, the supply and exhaust of nitrogen gas into and out of the chamber 6 start, and the semiconductor wafer W is transported into the chamber 6 by the transport robot (Step S31). Then, as in the first preferred embodiment, the lift pins 12 move upwardly to receive the semiconductor wafer W from the transport robot, and after the transport robot moves out of the heat treatment space 65, the lift pins 12 move downwardly, so that the semiconductor wafer W is placed on the support ring 77 (Step S32). When the semiconductor wafer W is placed on the support ring 77, the enclosed space 96 surrounded by the upper surface of the holding plate 75, the back surface of the semiconductor wafer W, and the inner wall surface of the support ring 77 is formed.

In the third preferred embodiment, the pressure in the enclosed space 96 is reduced by the aforementioned pressure reducing mechanism including the ejector 130 (Step S33). Specifically, the valve 132 is opened to feed the high-pressure nitrogen gas to the ejector 130, and the valve 123 is also opened. The negative pressure generated by the high-pressure nitrogen gas passing through the ejector 130 is exerted on the exhaust port 121, resulting in the pressure reduction in the enclosed space 96. As a result, as in FIG. 14 in the second preferred embodiment, the pressure in the space overlying the semiconductor wafer W supported by the support ring 77 becomes relatively higher than the reduced pressure in the enclosed space 96, so that the pressure difference arises between the space overlying the semiconductor wafer W and the enclosed space 96.

The details of subsequent processes in Steps S34 to S36 are the same as those in Steps S13 to S15 of FIG. 8, respectively. Specifically, after the semiconductor wafer W is supported by the support ring 77 and the pressure in the enclosed space 96 is reduced, the 40 halogen lamps HL in the halogen heating part 4 emit light to preheat the semiconductor wafer W (Step S34). The temperature of the semiconductor wafer W is measured by the lower radiation thermometer 20 when the halogen lamps HL perform the preheating. The controller 3 effects feedback control of the output from the halogen lamps HL so that the temperature of the semiconductor wafer W is equal to the preheating temperature T1, based on the value measured by the lower radiation thermometer 20.

The flash lamps FL in the flash heating part 5 irradiate the front surface of the semiconductor wafer W held by the susceptor 74 with a flash of light (Step S35) when a predetermined time period has elapsed since the temperature of the semiconductor wafer W reached the preheating temperature T1. By the irradiation with a flash of light which is extremely short in irradiation time and high in intensity, the front surface temperature of the semiconductor wafer W momentarily increases to the treatment temperature T2 of 1000° C. or higher, and thereafter decreases rapidly.

In the third preferred embodiment, as in the second preferred embodiment, there has been a pressure difference between the space overlying the semiconductor wafer W and the enclosed space 96 since before the flash irradiation, and the force pressing from above is exerted on the front surface of the semiconductor wafer W even when the temperature of the front surface of the semiconductor wafer W increases abruptly at the time of the flash irradiation. This suppresses the deformation of the semiconductor wafer W into a convex form at the time of the flash irradiation and prevents the semiconductor wafer W from jumping up from the susceptor 74. As a result, the third preferred embodiment reduces flaws in the back surface of the semiconductor wafer W resulting from the jumping of the semiconductor wafer W to prevent the semiconductor wafer W from cracking.

After a predetermined time period has elapsed since the completion of the flash heating treatment, the halogen lamps HL turn off. This causes the temperature of the semiconductor wafer W to decrease from the preheating temperature T1. After the temperature of the semiconductor wafer W is decreased to the predetermined temperature or below, the transport robot outside the heat treatment apparatus 1 transports the semiconductor wafer W out of the chamber 6 (Step S36).

In the third preferred embodiment, the pressure in the enclosed space 96 surrounded by the upper surface of the holding plate 75, the lower surface of the semiconductor wafer W, and the inner wall surface of the support ring 77 is reduced after the semiconductor wafer W is placed on the support ring 77. This causes the pressure difference to arise between the space overlying the semiconductor wafer W and the enclosed space 96, as in the second preferred embodiment. Thus, at the time of the flash irradiation, the force pressing from above is exerted on the front surface of the semiconductor wafer W due to the pressure difference to prevent the semiconductor wafer W from jumping, thereby preventing wafer cracking, as in the first preferred embodiment.

In the third preferred embodiment, the pressure in the enclosed space 96 is intentionally reduced. This allows the pressure difference to arise with reliability between the space overlying the semiconductor wafer W and the enclosed space 96. Thus, the force pressing from above is exerted more effectively on the semiconductor wafer W to prevent the semiconductor wafer W from jumping.

### <Modifications>

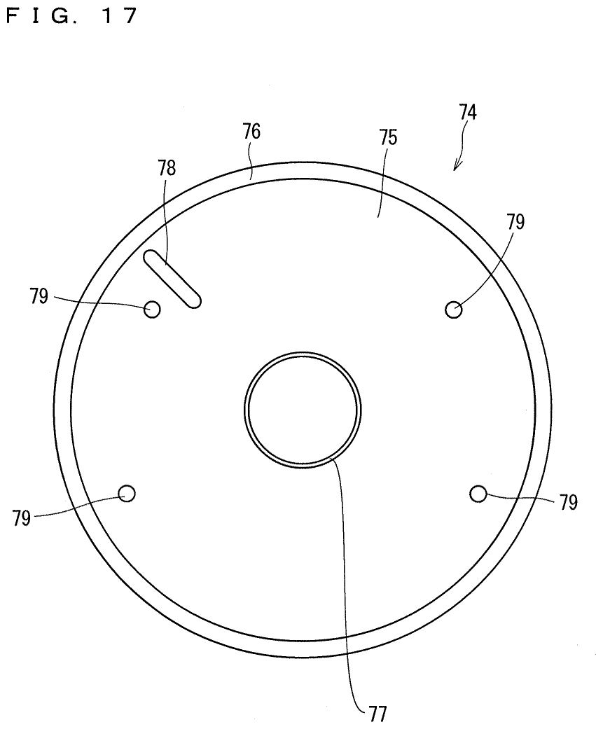

While the preferred embodiments according to the present invention have been described hereinabove, various modifications of the present invention in addition to those described above may be made without departing from the scope and spirit of the invention. For example, the annular support ring 77 with a diameter of 180 mm is provided on the holding plate 75 of the susceptor 74 in the first preferred embodiment. The present invention, however, is not limited to this. A variety of forms to be described below may be employed for the support ring 77. FIGS. 17 to 20 are plan views showing examples of other forms of the support ring 77.

In the example shown in FIG. 17, the support ring 77 having an annular shape with a diameter of 100 mm which is smaller than that of the first preferred embodiment is provided on the holding plate 75 of the susceptor 74. Even the support ring 77 with such a small diameter is capable of producing effects similar to those of the aforementioned preferred embodiments by placing the semiconductor wafer W thereon. The diameter of the support ring 77 is not limited to 180 mm or 100 mm, but may have any appropriate value which is able to support the semiconductor wafer W as long as the diameter of the support ring 77 is smaller than that of the semiconductor wafer W.

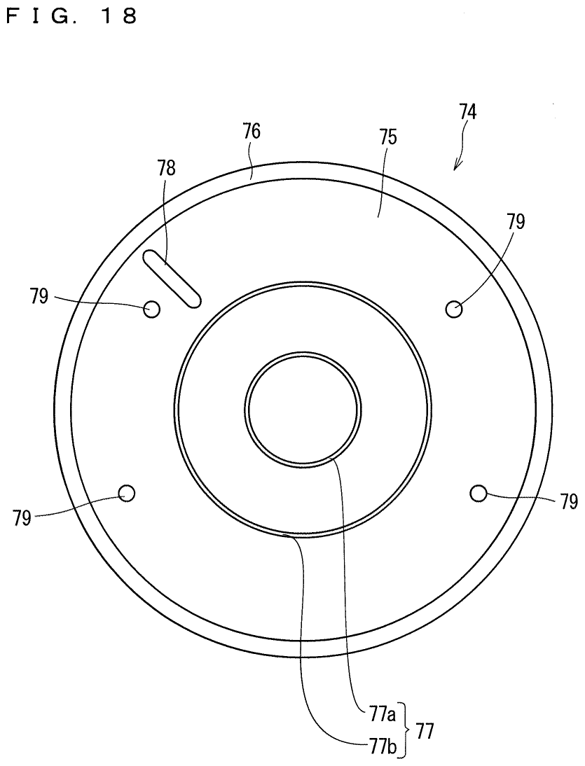

In the example of FIG. 18, the support ring 77 has a double-ring structure. Specifically, the support ring 77 is comprised of an inner ring 77a and an outer ring 77b. Each of the inner ring 77a and the outer ring 77b is a protrusion of quartz having an annular shape. The outer ring 77b has a diameter of, for example, 180 mm, and the inner ring 77a has a diameter of, for example, 90 mm. Both of the inner ring 77a and the outer ring 77b are disposed concentrically with the inner circumference of the guide ring 76. In the example of FIG. 18, when the semiconductor wafer W is placed on the inner ring 77a and the outer ring 77b, the following enclosed spaces are formed: an inner enclosed space surrounded by the upper surface of the holding plate 75, the lower surface of the semiconductor wafer W, and an inner wall surface of the inner ring 77a; and an outer enclosed space surrounded by the upper surface of the holding plate 75, the lower surface of the semiconductor wafer W, an outer wall surface of the inner ring 77a, and an inner wall surface of the outer ring 77b.

In the example of FIG. 18, the two enclosed spaces are formed by placing the semiconductor wafer W on the support ring 77, but effects similar to those of the aforementioned preferred embodiments are produced. When the example shown in FIG. 18 is applied to the third preferred embodiment, the pressures in the inner and outer enclosed spaces may be separately reduced to differ from each other. For example, the pressure in the outer enclosed space may be made relatively higher than that in the inner enclosed space (although the pressure in the outer enclosed space is lower than that in the space overlying the semiconductor wafer W). The support ring 77 may have a multiple-ring structure comprised of not less than three rings, as long as multiple annular support rings with different diameters are disposed concentrically.

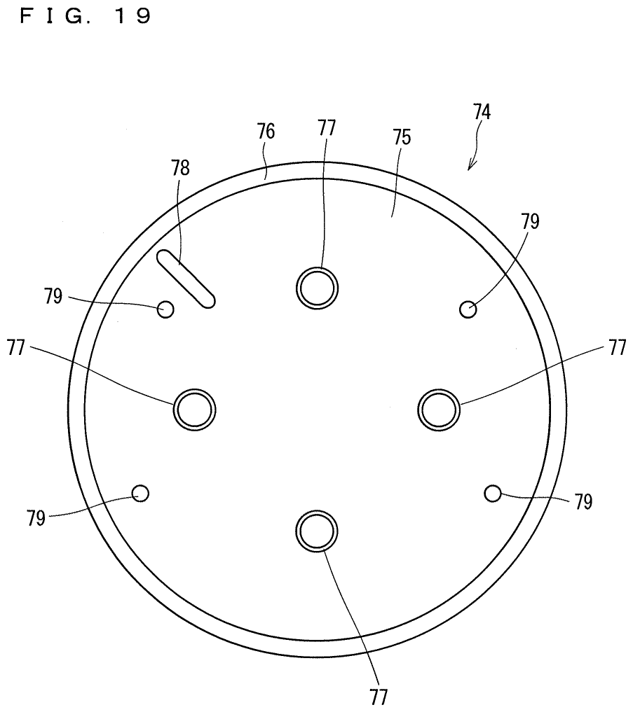

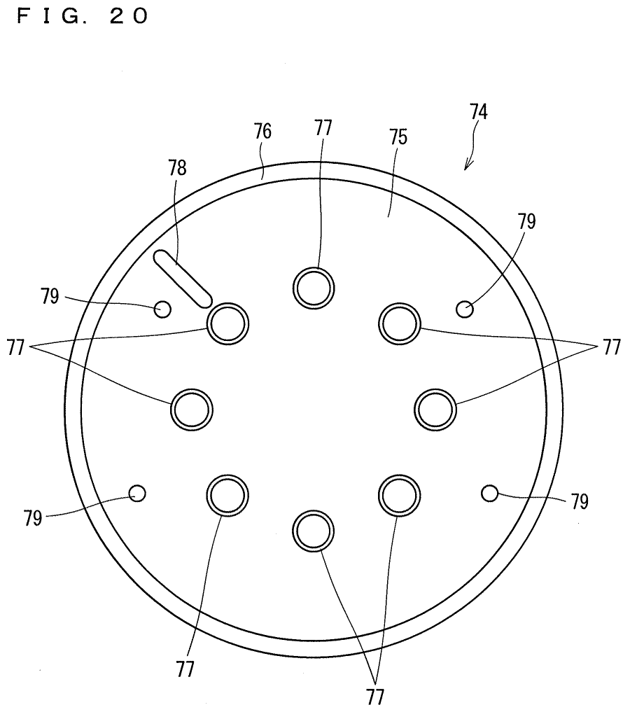

In the examples of FIGS. 19 and 20, multiple small-sized support rings 77 are provided on the holding plate 75 of the susceptor 74. In the example of FIG. 19, four support rings 77 are arranged at intervals of 90 degrees. In the example of FIG. 20, eight support rings 77 are arranged at intervals of 45 degrees. Each of the support rings 77 shown in FIGS. 19 and 20 is a protrusion of quartz having an annular shape with a diameter of, for example, 10 mm. In the examples of FIGS. 19 and 20, the semiconductor wafer W is supported by the multiple support rings 77. When the semiconductor wafer W is placed on the multiple support rings 77, multiple enclosed spaces are formed which are surrounded by the upper surface of the holding plate 75, the lower surface of the semiconductor wafer W, and inner wall surfaces of the respective support rings 77. This also produces effects similar to those of the aforementioned preferred embodiments. The number of support rings 77 provided in the susceptor 74 is not limited to four or eight, but may be any appropriate number.

The support ring 77 has an annular shape that is truly circular in the aforementioned preferred embodiments, but may have an elliptic or oval shape, for example. It is sufficient that the support ring 77 has an annular shape that is able to form an enclosed space using the upper surface of the holding plate 75, the lower surface of the semiconductor wafer W, and the inner wall surface of the support ring 77.

In the third preferred embodiment, the ejector 130 is used to reduce the pressure in the enclosed space 96. In place of this, a vacuum pump, for example, may be used to reduce the pressure in the enclosed space 96.

Although the 30 flash lamps FL are provided in the flash heating part 5 according to the aforementioned preferred embodiments, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiments, the filament-type halogen lamps HL are used as continuous lighting lamps that emit light continuously for not less than one second to perform the preheating treatment of the semiconductor wafer W. The present invention, however, is not limited to this. In place of the halogen lamps HL, discharge type arc lamps (e.g., xenon arc lamps) or LED lamps may be used as the continuous lighting lamps to perform the preheating treatment.

While the disclosure has been shown and described in detail, the foregoing description is in all aspects illustrative and not restrictive. It is therefore understood that numerous modifications and variations can be devised.

What is claimed is:

1. A heat treatment apparatus for irradiating a disk-shaped substrate with a flash of light to heat the substrate, comprising:
a chamber for receiving a substrate therein;
a susceptor for holding said substrate in said chamber, said susceptor including a holding plate of quartz having a planar shape, and a protrusion of quartz having an annular shape, said protrusion being provided upright on an upper surface of said holding plate and having a diameter smaller than that of said substrate; and
a flash lamp for irradiating said substrate held by said susceptor with a flash of light.

2. The heat treatment apparatus according to claim 1,
wherein an enclosed space surrounded by the upper surface of said holding plate, a lower surface of said substrate, and said protrusion is formed when said substrate is placed on said protrusion.

3. The heat treatment apparatus according to claim 2, further comprising
a pressure reducing mechanism for reducing pressure in said enclosed space.

4. The heat treatment apparatus according to claim 3,
wherein said pressure reducing mechanism includes
an exhaust port provided in said holding plate, and
an ejector for applying a negative pressure to said exhaust port.

5. The heat treatment apparatus according to claim 1,
wherein multiple protrusions each having an annular shape are disposed on the upper surface of said holding plate.

6. The heat treatment apparatus according to claim 5,
wherein said multiple annular protrusions have different diameters and are disposed concentrically on the upper surface of said holding plate.

7. The heat treatment apparatus according to claim 1, further comprising
a continuous lighting lamp for irradiating said substrate held by said susceptor with light to preheat said substrate before the said substrate is irradiated with said flash of light.

8. A method of irradiating a disk-shaped substrate with a flash of light to heat the substrate, comprising:
(a) causing a susceptor to hold a substrate in a chamber; and
(b) irradiating said substrate held by said susceptor with a flash of light from a flash lamp,
wherein said susceptor includes
a holding plate of quartz having a planar shape, and
a protrusion of quartz having an annular shape, said protrusion being provided upright on an upper surface of said holding plate and having a diameter smaller than that of said substrate, and
wherein said substrate is placed on said protrusion in said (a).

9. The method according to claim 8,
wherein an enclosed space surrounded by the upper surface of said holding plate, a lower surface of said substrate, and said protrusion is formed when said substrate is placed on said protrusion.

10. The method according to claim 9,
wherein pressure in said enclosed space is reduced.

11. The method according to claim 10,
wherein pressure in said chamber is reduced before said substrate is placed on said protrusion, and
wherein the pressure in said chamber is returned after said substrate is placed on said protrusion.

12. The method according to claim 8,
wherein light from a continuous lighting lamp is applied to said substrate held by said susceptor to preheat said substrate before said (b).
